(19) United States
(12) Patent Application Publication
(10) Pub. No.: US 2009/0121304 A1
(43) Pub. Date: May 14, 2009

(54) SOLID-STATE IMAGE PICKUP DEVICE, PROCESS FOR PRODUCING THE SAME AND ELECTRONIC DEVICE

(75) Inventor: Keiji Terada, Hiroshima (JP)

Correspondence Address: EDWARDS ANGELL PALMER & DODGE LLP, P.O. BOX 55874, BOSTON, MA, 02205, US

(73) Assignee: SHARP KABUSHIKI KAISHA, Osaka (JP)

(21) Appl. No.: 12/269,450

(22) Filed: Nov. 12, 2008

(30) Foreign Application Priority Data
Nov. 13, 2007 (JP) 2007-294895

(51) Int. Cl. H01L 31/0203; H01L 31/18

(52) U.S. Cl. 257/434; 438/64; 257/E31.11

(57) ABSTRACT

A camera module 10 comprises a solid-state image sensor 11 including a light receiving unit 11a and a cover glass 12 covering the light receiving unit 11a of the solid-state image sensor 11. A rough-surfaced side surface of the cover glass 12 reduces flare light by scattering light incident to the side surface of the cover glass 12. Therefore, the present invention provides the camera module 10 in which very versatile measures against flare reducing production of flare and applicable to reductions in the size of a chip of the solid-state image sensor 11 as well are taken.

This Nonprovisional application claims priority under U.S.C. § 119(a) on Patent Application No. 294895/2007 filed in Japan on Nov. 13, 2007, the entire contents of which are hereby incorporated by reference.

### FIELD OF THE INVENTION

The present invention relates to a solid-state image pickup device, a process for producing the same and an electronic device, and more particularly, to a solid-state image pickup device, a process for producing the same and an electronic device, in each of which effective measures against flare and ghosts are taken.

### BACKGROUND OF THE INVENTION

A solid-state image pickup device comprising a solid-state image sensor is provided with a cover glass (transparent member) so as to protect the solid-state image sensor. In the solid-state image pickup device, flare rays outside the visual field (flare light) transmitted through a lens and entered to a side surface of the cover glass are reflected on the side surface of the cover glass and reach a light receiving unit of the solid-state image sensor. As a result, flare (ghost) is produced on an image by the light reaching the light receiving unit.

For example, in Patent Document 1, a solid-state image pickup device (camera module) in which measures against flare are taken is disclosed. Specifically, the device disclosed in Patent Document 1 is provided with a cover glass so that flare rays outside the visual field reflected on the side surface of the cover glass will not be incident to the light receiving unit of the solid-state image sensor. FIG. 7 is a cross-sectional view of the solid-state image pickup device disclosed in Patent Document 1 in which measures against flare are taken.

As illustrated in FIG. 7, in the solid-state image pickup device 100 disclosed in Patent Document 1, a gap is formed between a side surface of a cover glass 112 on a board 113 and a light receiving unit 111a of a solid-state image sensor 111 (imaging unit in practical use). The solid-state image pickup device 100 is configured so that flare rays outside the visual field will not be incident to the light receiving unit 111a by guiding the flare rays outside the visual field to the gap. With this configuration, the flare rays outside the visual field incident through the course b′ illustrated in the drawing is prevented from being reflected at the point rb′ on the side surface of the cover glass 112. Also the flare rays outside the visual field incident through the course a′ illustrated in the drawing directly reach the board 113 after reflected at the point ra′ on the side surface of the cover glass 112.

Thus, in the solid-state image pickup device 100 comprising the solid-state image sensor 111 and the cover glass 112 for protecting the solid-state image sensor 111, disclosed in Patent Document 1, a gap of a certain distance or longer is secured between the end of the cover glass 112 and the end 111b of the light receiving unit 111a of the solid-state image sensor 111. This prevents the flare rays reflected on the side surface of the cover glass 112 from being incident to the light receiving unit 111a.

Even in the solid-state image pickup device disclosed in Patent Document 1, the measures against flare are not sufficient. For this reason, more efficient measures against flare are required.

Specifically, in Patent Document 1, no measures against flare have been taken on the side surface of the cover glass, which means that fundamental measures against flare have not been taken. Moreover, the light incident to the side surface of the cover glass contains components of different wavelengths. Since angles of reflection of each wavelength component differ, it is necessary to set the cover glass in consideration of the angles of reflection of all the wavelength components. For this reason, setting of the cover glass will be enormously complicated and accordingly designing of an optical system, such as a lens, will also be considerably restricted.

Furthermore, a chip of the solid-state image sensor has been and acceleratingly will be reduced in size. As for measures against flare in the solid-state image pickup device disclosed in Patent Document 1, however, it is necessary to secure a gap of a certain distance or longer between the end of the cover glass 112 and the end 111b of the light receiving unit 111a of the solid-state image sensor 111. For this reason, as the chip of the solid-state image sensor is reduced in size, it will be extremely difficult to apply the measures against flare disclosed in Patent Document 1. That is, the configuration disclosed in Patent Document 1 will be restricted in terms of the positional arrangement of the light receiving unit 111a and the cover glass 112.

[Patent Document 1] Japanese Unexamined Patent Application Publication No. 8-160339 (Published on Jun. 21, 1996)

### SUMMARY OF THE INVENTION

The present invention is made in consideration of the aforementioned problems. It is an object of the present invention to provide a solid-state image pickup device, a process for producing the same and an electronic device in each of which production of flare can be reduced. Another object of the present invention is to provide a solid-state image pickup device, a process for producing the same and an electronic device in each of which very versatile measures against flare are taken, and which is also applicable to reductions in a size of a chip of the solid-state image sensor.

In order to attain the object thereby to solve the aforementioned problems, a solid-state image pickup device comprises a solid-state image sensor mounted on a board and including a light receiving unit and a transparent member facing said light receiving unit of said solid-state image sensor and having a gap between itself and said solid-state image sensor, and said transparent member has a side surface having a rough-surfaced shape for scattering light incident to the side surface.

According to the present invention, the rough-surfaced shape is formed on the side surface of the transparent member. For this reason, the light incident to the side surface of the transparent member is scattered by the rough-surfaced shape on the side surface of the transparent member. This reduces the light entering the side surface of the transparent member and being reflected from there to the side surface of the light receiving unit of the solid-state image sensor. That is, this reduces the light reflected on the side surface of the transparent member and guided to the light receiving unit of the solid-state image sensor (flare light). Therefore, production of flare and ghosts can be reduced to the extent sufficient in practical use.

Moreover, since the production of flare and ghosts can be reduced simply by rough-surfacing the side surface of the transparent member, the present invention can also cope with reductions in the size of a chip of the solid-state image sensor. That is, even if the solid-state image sensor is miniaturized, the present invention can cope with the miniaturization by changing the form of the side surface of the transparent member. Therefore, the solid-state image pickup device in which very versatile measures against flare are taken can be provided without restricted by the size of a chip of the solid-state image sensor.

Furthermore, while the solid-state image pickup device disclosed in Patent Document 1 controls production of flare by using the cover glass (transparent member) that is intentionally larger than normal, the solid-state image pickup device in the present invention uses the transparent member whose side surface is rough-surfaced. For this reason, measures against flare not to converge the flare light at the light receiving unit can be taken without changing the size of the transparent member.

In order to attain the object, a method according to the present invention is a method for manufacturing a solid-state image pickup device comprising a solid-state image sensor mounted on a board and including a light receiving unit and a transparent member facing said light receiving unit of said solid-state image sensor and having a gap between itself and said solid-state image sensor, and said method comprises a process for rough-surfacing a side surface of said transparent member.

According to the present invention, a solid-state image pickup device is produced using a transparent member whose side surface is rough-surfaced. For this reason, the light incident to the side surface of the transparent member is scattered by the rough-surfaced shape on the side surface of the transparent member. This reduces the light entering the side surface of the transparent member and being reflected from there to the side surface of the light receiving unit of the solid-state image sensor. That is, this reduces the light reflected on the side surface of the transparent member and guided to the light receiving unit of the solid-state image sensor (flare light). Therefore, production of flare and ghosts can be reduced to the extent sufficient in practical use.

Moreover, since the production of flare and ghosts can be reduced simply by rough-surfacing the side surface of the transparent member, the aforementioned process can also be applied to reductions in the size of a chip of the solid-state image sensor. Therefore, regardless of the size of a chip, the solid-state image pickup device in which very versatile measures against flare and ghosts are taken can be produced.

Furthermore, in order to attain the object, an electronic device according to the present invention comprises a solid-state image pickup device comprising a solid-state image sensor mounted on a board and including a light receiving unit and a transparent member facing said light receiving unit of said solid-state image sensor, having a gap between itself and said solid-state image sensor and having a side surface having a rough-surfaced shape for scattering light incident to the side surface. According to the present invention, the electronic device in which very versatile measures against flare are taken can be provided.

Additional objects, features, and strengths of the present invention will be made sufficiently clear by the description below. Moreover, the advantages of the present invention will be evident from the following explanation in reference to the appended drawings.

### BRIEF DESCRIPTION OF THE DRAWINGS

FIG. 1 is a cross-sectional view of a camera module according to one embodiment of the present invention.

FIG. 2 is a conceptual diagram showing a concept of a method for evaluation of production of flare in the embodiment of the present invention.

FIG. 3 is a perspective and side view of a cover glass formed by dicing.

FIG. 4 is a perspective and side view of a cover glass formed by laser irradiation.

FIG. 5 is an image picked up by the solid-state image pickup device comprising the cover glass illustrated in FIG. 3.

FIG. 6 is an image picked up by the solid-state image pickup device comprising the cover glass illustrated in FIG. 4.

FIG. 7 is a cross-sectional view showing a solid-state image pickup device disclosed in Patent Document 1.

### DESCRIPTION OF THE EMBODIMENTS

The following is a description of one embodiment of the present invention based on drawings.

A solid-state image pickup device of the present invention is configured such that a cover glass adhered to an upper side surface of a solid-state image sensor has a side surface having a rough-surfaced shape. With this configuration, the solid-state image pickup device of the present invention reduces flare rays incident to the side surface of the cover glass.

The solid-state image pickup device is suitable for electronic devices with the function of imaging, such as camera-equipped mobile phones, digital cameras, video cameras and security cameras. In the present embodiment, a camera module (solid-state image pickup device) applicable to camera-equipped mobile phones is to be described.

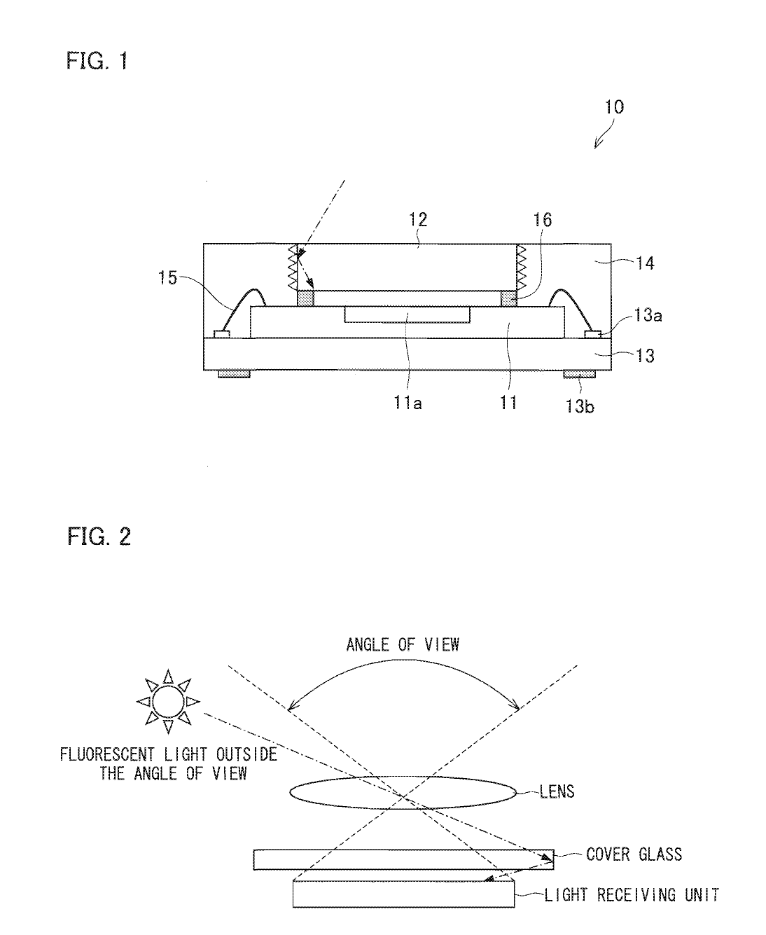

FIG. 1 is a cross-sectional view of a camera module 10 of the present embodiment. The camera module 10 includes a solid-state image sensor 11 mounted on a circuit board 13 and a cover glass 12 arranged to face the solid-state image sensor 11.

Furthermore, the camera module 10 comprises an imaging optical system (lens) (not illustrated) for forming a subject image. The subject image formed by the imaging optical system is converted into an electrical signal by the solid-state image sensor 11. An optical center of the imaging optical system coincides with that of the solid-state image sensor 11.

The circuit board 13 is a board where a circuit pattern (not illustrated) is formed. The circuit board 13 is, for example, a printed circuit board or a ceramic board. On the side surface of the circuit board 13, where the solid-state image sensor 11 is mounted, a wire bond terminal 13a (not illustrated) is provided and on the opposite side surface (back side surface), an electrode for external connection 13b is provided. The wire bond terminal 13a and the electrode for external connection 13b are electrically connected with each other.

Moreover, the wire bond terminal 13a is electrically connected with the solid-state image sensor 11 provided on a central part of the circuit board 13 by a wire 15 and transmission of electrical signals is possible between the wire bond terminal 13 and the solid-state image sensor 11. Furthermore, the electrode for external connection 13b enables input and output of signals between the camera module 10 and a camera-equipped mobile phone (electronic device) equipped with the camera module 10.

The solid-state image sensor 11, which includes a semi-conductor chip, converts a subject image formed by an imaging optical system (not illustrated) into an electrical signal. That is, the solid-state image sensor 11 is a sensor device for converting the light incident from the imaging optical system of the camera module 10 into photoelectricity. The solid-state image sensor 11 is, for example, CCD or CMOS sensor IC.

The solid-state image sensor 11 is adhered to the circuit board 13 by a die bond member (not illustrated) and, a pad of the solid-state image sensor 11 (not illustrated) and the wire bond terminal 13a of the circuit board 13 are electrically connected by the wire 15 (connection unit).

On the surface of the solid-state image sensor 11, the light receiving unit 11a (pixel area) is formed. The light receiving unit 11a is a region (light transmission region) though which the light incident from the imaging optical system (not illustrated) is passed. The solid-state image sensor 11 converts a subject image formed on the light receiving unit 11a into an electrical signal and outputs the signal as an analogue image signal. That is, photoelectric conversion is carried out at the light receiving unit 11a.

On the light receiving unit 11a of the solid-state image sensor 11, the cover glass 12 is arranged via an adhesion layer 16 formed from adhesive resin.

The cover glass 12 is a transparent member, made of glass or resin, and the like. On the surface of the cover glass 12 (the side surface on which an imaging optical system (i.e. lens) is arranged), a film blocking infrared rays can be formed. This enables the cover glass 12 to be equipped with the function of blocking infrared rays as well.

The adhesion layer 16 adheres the solid-state image sensor 11 to the cover glass 12. The adhesion layer 16, which is formed on a periphery of the light receiving unit 11a of the solid-state image sensor 11, adheres the cover glass 12 to the top of the solid-state image sensor 11. In this way, the cover glass 12 covers the light receiving unit 11a of the solid-state image sensor 11.

More specifically, the adhesion layer 16 adheres the solid-state image sensor 11 to the cover glass 12 so that the cover glass 12 will face the light receiving unit 11a of the solid-state image sensor 11 with a gap between itself and the solid-state image sensor 11. Here the cover glass 12 is adhered so that there will be sealed space between the cover glass 12 and the solid-state image sensor 11. With such sealed space formed, entry of moisture to the light receiving unit 11a and penetration and attachment of dust to the light receiving unit 11a can be prevented. Therefore, production of defectives at the light receiving unit 11a can be prevented. Moreover, in the present embodiment, the cover glass 12 will not come off since the adhesion layer 16 is formed throughout the periphery of the light receiving unit 11a.

Furthermore, for example, the adhesion layer 16 can be formed by patterning, where processing, such as exposure and development, is done with photolithography technique after a sheet-type adhesive is applied on the surface of the solid-state image sensor 11. The photolithography technique enables highly-accurate patterning of the adhesion layer 16. Moreover, the photolithography technique can make the thickness of the adhesion layer 16 uniform since a sheet-type adhesive is used. This enables highly-accurate adhesion of the cover glass 12 to the light receiving unit 11a of the solid-state image sensor 11.

In the present embodiment, the solid-state image sensor 11 is mounted on the circuit board 13. A Component such as an IC or chip component other than the solid-state image sensor 11 may be mounted on the circuit board 13. For example, it is possible to form a stacking structure by providing an IC chip in addition to the solid-state image sensor 11. In this case, the solid-state image sensor 11 is arranged at the top in the stacking structure. Furthermore, the circuit board 13 can be provided with an electronic component, such as DSP (digital signal processor) which controls the movement of the solid-state image sensor 11 and processes the signal output from the solid-state image sensor 11, CPU which does a variety of arithmetic processing according to a program, ROM which stores the program, or RAM which stores the data of each processing process, though not illustrated in the drawing. In this case, the whole camera module 10 is controlled by each electronic component.

In the camera module 10 of the present embodiment, each of the members on the circuit board 13 is sealed with mold resin 14. That is, the camera module 10 has a so-called CSP (Chip Scale Package) structure. In other words, in the camera module 10, the solid-state image sensor 11, including the wire 15 which electrically connects the solid-state image sensor 11 to the circuit board 13, is sealed with the mold resin 14. For this reason, the configuration of the camera module 10 is suitable for making the module extremely miniature and thin.

Furthermore, the area except the light transmission region of the camera module 10 is sealed with the mold resin 14. Therefore, the surface of the cover glass 12 is not covered by the mold resin 14 and light is transmitted through the light receiving unit 11a of the solid-state image sensor 11.

Here a characteristic part of the camera module 10 is to be described. The camera module 10 is most characteristic in a form of the side surface of the cover glass 12. Specifically, in the camera module 10, a rough-surfaced shape is formed on the side surface of the cover glass 12.

Normally, a cover glass of a camera module is formed through cutting a glass board by laser irradiation. This is because lasers are highly-linear rays, or because in the case of cutting a glass board by laser irradiation, the form of the cover glass is stable and an amount of dust produced at the timing of cutting is small. However, the inventor of the present invention considers a surface cut by laser irradiation schematically flat, as set forth below. When the side surface of the cover glass is flat as set forth above, flare rays incident to the side surface of the cover glass are evenly (or entirely) reflected on the side surface of the glass and converged at the light receiving unit of the solid-state image sensor. As a result, flare and ghosts are produced on an image. Therefore, measures against flare and ghosts of the existing camera module are insufficient.

So in the camera module 10 of the present embodiment, the side surface of the cover glass 12 is rough-surfaced. This scatters the light (flare light) reflected on the side surface of the cover glass 12 and incident to the light receiving unit 11a of the solid-state image sensor 11. For this reason, the flare light will not be converged at the light receiving unit 11a. That is, the flare light can be reduced. Therefore, production of flare and ghosts on an image can be reduced to the extent sufficient in practical use.

As set forth above, in the camera module 10, the rough-surfaced side surface of the cover glass 12 scatters the light incident to the side surface of the cover glass 12 and consequently reduces the amount of the light entering from the side surface of the cover glass 12 to the light receiving unit 11a (imaging surface) of the solid-state image sensor 11. Therefore, defect-causing flare rays reflected on the side surface of the cover glass 12 can be reduced.

This rough-surfaced shape is not particularly limited as long as the shape can scatter the light incident to the side surface of the cover glass 12. However, it is preferable that the rough-surfaced shape should be made randomly on the side surface of the cover glass 12, or a rough-surfaced shape without regularity should be made randomly on the side surface of the cover glass 12. This enables scattered reflection of the light incident to the side surface of the cover glass 12. Thus, this is more certain to reduce reflection on the side surface of the cover glass 12 and incidence to the light receiving unit 11a of the solid-state image sensor 11, or to reduce the light reflected on the side surface of the cover glass 12 and incident to the light receiving unit 11a of the solid-state image sensor 11 (flare light).

Moreover, for example, the preferable height of the salient of this rough-surfaced shape on the side surface of the cover glass 12 is not lower than 0.9 μm but not higher than 5 μm, which enables the rough-surfaced shape on the side surface of the cover glass 12 to scatter the flare light effectively. Therefore, production of flare and ghosts on an image can be controlled more effectively. Furthermore, the height of the salient shows a distance between the bottom (valley) of the lowest reentrant and the end of the salient (mountain), or TTV (Total thickness Variation).

Here in the camera module 10, flare produced on an image because of the light passing through the inside of the cover glass 12 and reflected on the side surface of the cover glass 12 totally (specularly) can be controlled by the rough-surfaced shape formed on the side surface of the cover glass 12 (or by roughening the side surface of the cover glass 12). In geometrical optics, the condition at the timing of total reflection is drawn out by an empirical rule. However, geometrical optics rests on the premise that the boundary surface, where a reflective index varies, is flat and mirrored. For simplification, the design of the rough-surfaced shape of the cover glass 12 of the present embodiment is based on the premise that the light incident to the side surface (the boundary surface of reflection) of the cover glass 12 temporarily goes straight, which is approximated to the condition in geometrical optics as a block against total reflection, where rays are scattered and diffused around the boundary surface of reflection by the rough-surfaced shape formed on the cover glass 12 (where there is a block preventing the light from going straight around the boundary). That is, the rough-surfaced shape of the cover glass 12 is a scattering object, which scatters the light around the boundary surface of reflection. For this reason, the rough-surfaced shape can prevent the light from going straight as long as it is a block bigger than the wavelength of the light.

Since the wavelength of the light is from 360 nm (0.36 μm) to 830 nm (0.83 μm), the height of the salient set at not lower than 0.9 μm can prevent the light from going straight on the side surface of the cover glass 12 and cause non-selective scattering. If the height of the salient is set at lower than 0.9 μm, however, the light might be dispersed or deflected by Mie scattering and Rayleigh scattering.

Furthermore, if the height of the salient is not lower than 0.9 μm but not higher than 5 μm, it is easy to set the diamond particle size of the dicing blade (like a sandpaper with minimum diamond particles embedded) for cutting the cover glass 12, as set forth below.

Moreover, the rough-surfaced shape on the side surface of the cover glass 12 may be formed in consideration of the essential conditions for reflection (electromagnetism or quantum mechanics) for scattered reflection (diffuse reflection) of the flare light.

As set forth above, in the camera module 10 of the present invention, measures against flare are taken with attention paid to the form of the side surface of the cover glass 12. That is, the side surface of the cover glass 12 is rough-surfaced so that the light incident to the cover glass 12 will be scattered. For this reason, the light incident to the side surface of the cover glass 12 is scattered by the rough-surfaced shape on the side surface of the cover glass 12. This reduces the light entering the side surface of the cover glass 12 and being reflected from there to the side surface of the light receiving unit 11a of the solid-state image sensor 11. That is, this reduces the light reflected on the side surface of the cover glass 12 and guided to the light receiving unit 11a of the solid-state image sensor 11 (flare light). Therefore, production of flare and ghosts can be reduced to the extent sufficient in practical use.

Furthermore, since the production of flare and ghosts can be reduced simply by rough-surfacing the side surface of the cover glass 12, the present invention can also cope with reductions in the size of a chip of the solid-state image sensor 11. Therefore, regardless of the size of a chip, the camera module 10 in which very versatile measures against flare and ghosts are taken can be produced.

A method for forming the rough-surfaced shape on the side surface of the cover glass 12 is not particularly limited. For example, the rough-surfaced shape can be formed by dicing as set forth below. Specifically, the cut surface can be the side surface of the cover glass 12 when plural pieces of the cover glass 12 are cut and formed through cutting a glass board (transparent board) by dicing.

The cut surface prepared by dicing is rough, not like the flat one prepared by laser irradiation. That is, the cut surface prepared by dicing is rough-surfaced. This enables simple and easy formation of the rough-surfaced shape of the cover glass 12 as set forth above.

Moreover, the rough-surfaced shape of the side surface of the cover glass 12 can be formed by other methods than dicing, such as etching, chemical processing on the flat cover glass formed by laser irradiation, and spraying of particles of sandpapers, sands or diamonds.

Furthermore, the thickness of the cover glass 12 is not particularly limited since it varies depending on the rough-surfaced shape formed on the side surface. For example, if the rough-surfaced shape on the side surface of the cover glass 12 is formed highly densely, the light incident to the side surface is easily scattered. For this reason, reducing the thickness of the cover glass 12 is possible in this case.

The configuration of the camera module 10 is the same as that of the existing camera module except that the camera module 10 comprises the rough-surfaced shape on the side surface of the cover glass 12. For this reason, the camera module 10 can be produced basically through the existing manufacturing process or according to the existing process for manufacturing the camera module (e.g. the procedure disclosed in Japanese Unexamined Patent Application Publication No. 2004-296453) except the process for forming the rough-surfaced shape on the side surface of the cover glass 12.

Here the process for forming a rough-surfaced shape on the cover glass 12 comprises a cutting process for cutting a glass board by dicing and forming plural pieces of the cover glass 12. In the aforementioned cutting process, it is preferable to cut a transparent board so that the cut surface prepared by dicing will be the side surface of the cover glass 12. In such cutting process, one glass board is cut by dicing and plural pieces of the cover glass 12 are formed and also the side surface of the cover glass 12 is constituted by the cut surface prepared by dicing.

Here the cut surface prepared by dicing is rough, not like the flat one prepared by laser irradiation. Therefore, in the cutting process, the rough cut surface prepared by dicing can be the side surface of the cover glass 12. This enables simultaneous formation of plural pieces of the cover glass 12 from a glass board and a rough-surfaced shape on the side surface of the cover glass 12 with one step of the cutting process.

Moreover, the camera module 10 can be produced by forming a wafer comprising plural circuit boards 13 and the solid-state image sensor 11 mounted on each circuit board 13 and placing a piece of the cover glass 12 with a rough-surfaced shape formed on the side surface opposite the light receiving unit 11a of each solid-state image sensor 11.

Furthermore, concerning the wafer, each cover glass 12 and the rough-surfaced shape on the side surface of each cover glass 12 can be formed through placing a glass board of the same form as the wafer opposite the light receiving unit 11a of the solid image sensor 11 and cutting the glass board by dicing. Moreover, each camera module 10 can be formed through cutting wafers by dicing. In this case, formation of the cover glass 12 and the rough-surfaced shape on the side surface of the cover glass 12 by dicing as well as split of a camera module 10 from a wafer can be carried out through the same process.

### EMBODIMENTS

In the following embodiment, flare produced on images is estimated by a cover glass 12 with rough-surfaced shape formed on the side surface and the existing cover glass with the flat side surface.

FIG. 2 is a conceptual diagram of the method for evaluation of flare by the present embodiment. As illustrated in FIG. 2, with a fluorescent light on, the light outside the angle of field is incident to the cover glass and the incident light is reflected on the side surface of the cover glass. For this reason, it is easy for the light outside the angle of field to be incident to the light receiving unit of the solid-state image sensor and for flare to be produced. The present embodiment compares images picked up under such condition where flare is easy to be produced.

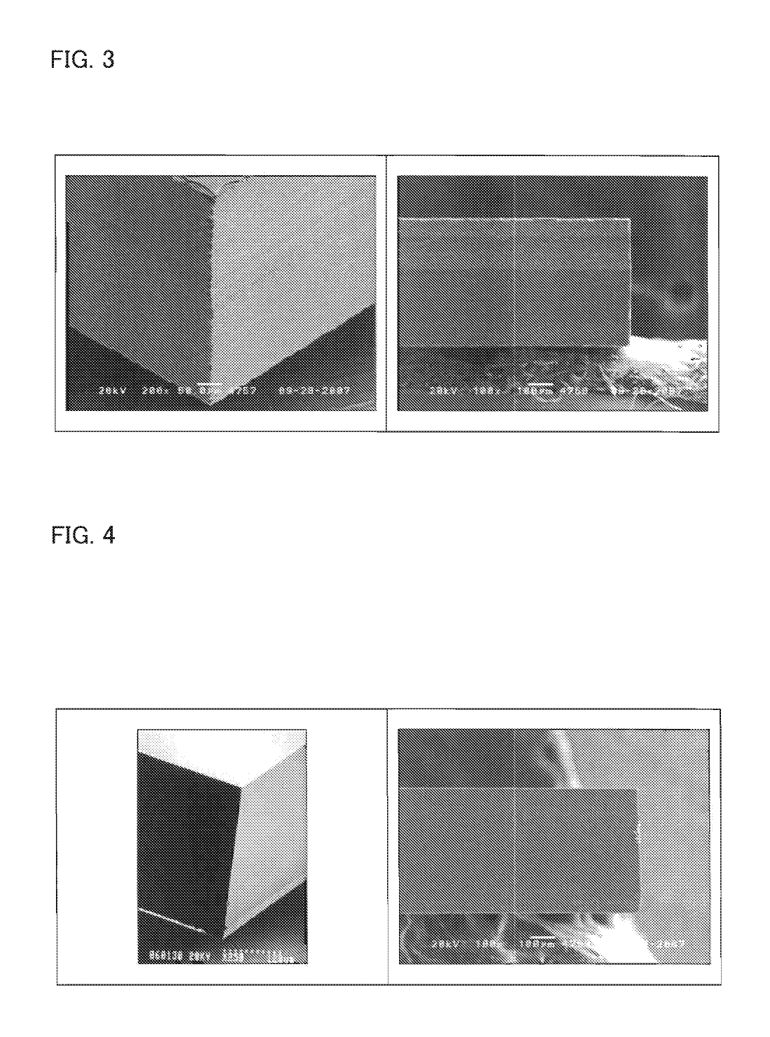

FIG. 3 is a perspective and side view of the cover glass formed by dicing. On the other hand, FIG. 4 is a perspective and side view of the cover glass formed by laser irradiation.

As illustrated in FIG. 3, when the side surface of the cover glass is the cut surface prepared by dicing, a rough-surfaced shape is formed on the side surface of the cover glass. Considering that the reduced scale of FIG. 3 perspective view is 50 μm, the rough-surfaced shape of not higher than 5 μm is randomly formed on the side surface of the cover glass.

As illustrated in FIG. 4, on the other hand, when the side surface of the cover glass is the cut surface prepared by laser irradiation, the side surface of the cover glass is flat.

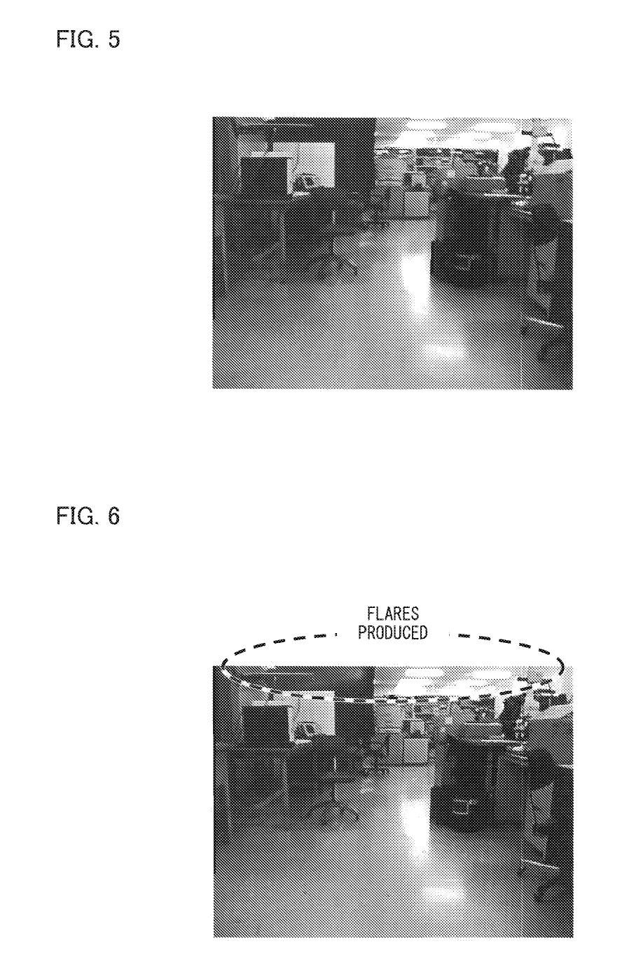

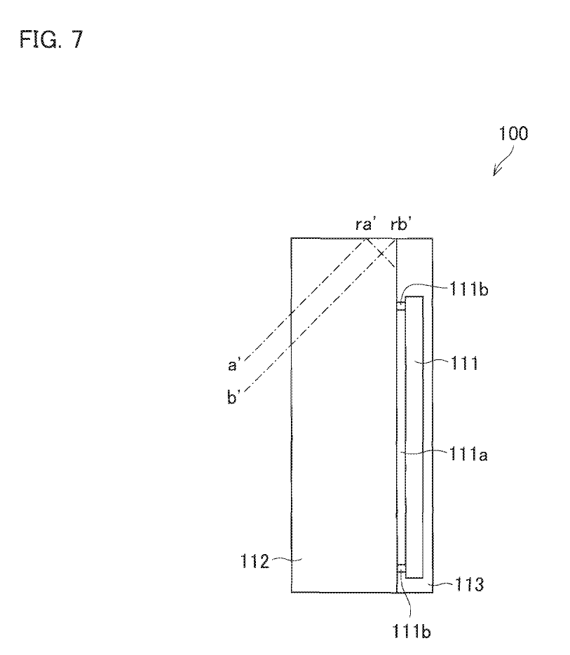

FIG. 5 is an image picked up by the solid-state image pickup device using FIG. 3 cover glass. FIG. 6 is an image picked up by the solid-state image pickup device using FIG. 4 cover glass. While no flare was found on FIG. 5 image, flare was produced on the top of FIG. 6 image. It was considered that this result was obtained because of reductions in the amount of reflection from the side surface of the cover glass to the light receiving unit of the solid-state image sensor of the light outside the angle of field incident from the outside of the angle of field to the side surface of the cover glass.

Thus, it was confirmed that production of flare can be reduced by making the side surface of the cover glass rough-surfaced.

As set forth above, the solid-state image pickup device of the present invention is configured such that a transparent member has a side surface having a rough-surfaced shape for scattering light incident to the side surface. This brings good effects that production of flare and ghosts can be reduced to the extent sufficient in practical use as well as that regardless of the size of a chip of the solid-state image sensor, the solid-state image pickup device in which very versatile measures against flare are taken can be provided.

In the solid-state image pickup device of the present invention, it is preferable that the rough-surfaced shape has a random shape.

According to the present invention, the rough-surfaced shape without regularity is formed randomly on the side surface of the transparent member. This enables scattered reflection of the light incident to the side surface of the transparent member. Thus, this is more certain to reduce reflection on the side surface of the transparent member and incidence to the light receiving unit of the solid-state image sensor, or to reduce the light reflected on the side surface of the transparent member and incident to the light receiving unit of the solid-state image sensor (flare light).

In the solid-state image pickup device of the present invention, it is preferable that the side surface of the transparent member have salients of not lower than 0.9 μm but not higher than 5 μm.

According to the present invention, the salient of not lower than 0.9 μm but not higher than 5 μm is formed on the side surface of the transparent member, which enables secure scattering of the light incident to the side surface of the transparent member. Therefore, it is possible to control production of flare and ghosts on an image more effectively.

Furthermore, the height of the salient shows a distance between the bottom (valley) of the lowest reentrant and the end of the salient (mountain), or TTV (Total thickness Variation).

In the solid-state image pickup device of the present invention, it is preferable that the rough-surfaced shape of the transparent member be constituted by a cut surface prepared by dicing. The cut surface prepared by dicing is rough, not like the flat one prepared by laser irradiation. According to the present invention, such rough surface formed by dicing is rough-surfaced on the side surface of the transparent member. Therefore, the solid-state image pickup device wherein the rough-surfaced shape of the transparent member for taking measures against flare and ghosts can be formed simply and easily can be provided.

In the solid-state image pickup device of the present invention, it is preferable that the transparent member be arranged on the solid-state image sensor via the adhesion layer.

According to the present invention, a thin solid-state image pickup device can be provided since the transparent member is arranged on the solid-state image sensor via the adhesion layer.

As set forth above, a method according to the present invention is a method for manufacturing a solid-state image pickup device comprising a solid-state image sensor mounted on a board and including a light receiving unit and a transparent member facing the light receiving unit of the solid-state image sensor and having a gap between itself and the solid-state image sensor, and the method comprising rough-surfacing a side surface of the transparent member.

According to the present invention, a solid-state image pickup device is produced using a transparent member whose side surface is rough-surfaced. For this reason, the light incident to the side surface of the transparent member is scattered by the rough-surfaced shape on the side surface of the transparent member. This reduces the light entering the side surface of the transparent member and being reflected from there to the side surface of the light receiving unit of the solid-state image sensor. That is, this reduces the light reflected on the side surface of the transparent member and guided to the light receiving unit of the solid-state image sensor (flare light). Therefore, production of flare and ghosts can be reduced to the extent sufficient in practical use.

Moreover, since the production of flare and ghosts can be reduced simply by rough-surfacing the side surface of the transparent member, the aforementioned process can also be applied to reductions in the size of a chip of the solid-state image sensor. Therefore, regardless of the size of a chip, the solid-state image pickup device in which very versatile measures against flare and ghosts are taken can be produced.

In the method for manufacturing a solid-state image pickup device of the present invention, the step of rough-surfacing includes: cutting a transparent board by dicing to form plural transparent members, so as to prepare a cut surface as the side surface of the transparent member by the dicing.

According to the present invention, in the cutting process, one transparent board is cut by dicing and plural transparent members are formed, and also the side surface of the transparent member is constituted by the cut surface prepared by dicing.

Here the cut surface prepared by dicing is rough, not like the flat one prepared by laser irradiation. According to the present invention, the rough cut surface formed by dicing can be the side surface of the transparent member. This enables simultaneous formation of plural transparent members and a rough-surfaced shape on the side surface of the transparent member from a transparent board with one step of the cutting process.

The present invention can be applied to various imagers (electronic devices), such as camera-equipped mobile phones, digital still cameras, security cameras, cameras for mobile phones, for mounting on vehicles, and for intercoms. Moreover, according to the present invention, effective measures against flare can be taken in various imagers without preventing miniaturization of the devices.

The present invention is not limited to the description of the embodiments above, but may be altered variously within the scope of the claims. That is, an embodiment based on a proper combination of technical means, which have been altered appropriately within the scope of the claims, is encompassed in the technical scope of the present invention.

The embodiments and concrete examples of implementation discussed in the aforementioned detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A solid-state image pickup device comprising:
a solid-state image sensor mounted on a board, and including a light receiving unit; and
a transparent member facing said light receiving unit of said solid-state image sensor and having a gap between itself and said solid-state image sensor,
said transparent member having a side surface having a rough-surfaced shape for scattering light incident to the side surface.

2. The solid-state image pickup device as set forth in claim 1 wherein said rough-surfaced shape has a random shape.

3. The solid-state image pickup device as set forth in claim 1 wherein the side surface of said transparent member has salients of not lower than 0.9 μm but not higher than 5 μm.

4. The solid-state image pickup device as set forth in claim 1 wherein the rough-surfaced shape of said transparent member is constituted by a cut surface prepared by dicing.

5. The solid-state image pickup device as set forth in claim 1 wherein said transparent member is arranged on said solid-state image sensor via an adhesion layer.

6. A method for manufacturing a solid-state image pickup device comprising: a solid-state image sensor mounted on a board, and including a light receiving unit; and a transparent member facing said light receiving unit of said solid-state image sensor and having a gap between itself and said solid-state image sensor, the method comprising;
rough-surfacing a side surface of said transparent member.

7. The method as set forth in claim 6, wherein:
the step of rough-surfacing includes:
cutting a transparent board by dicing to form plural transparent members, so as to prepare a cut surface as the side surface of the transparent member by the dicing.

8. An electronic device comprising:
a solid-state image pickup device,
said solid-state image pickup device comprising:
a solid-state image sensor mounted on a board, and including a light receiving unit; and
a transparent member facing said light receiving unit of said solid-state image sensor and having a gap between itself and said solid-state image sensor,
said transparent member having a side surface having a rough-surfaced shape for scattering light incident to the side surface.
